(19) United States
(12) Patent Application Publication
(10) Pub. No.: US 2008/0043795 A1
(43) Pub. Date: Feb. 21, 2008

(54) Light-Emitting Device

(75) Inventors: Han Tsung Hsueh, Taipei City (TW); Wen Yung Yeh, Hsinchu County (TW); Jim Yong Chi, Taichung City (TW)

Correspondence Address: WPAT, PC;INTELLECTUAL PROPERTY ATTORNEYS, 2030 MAIN STREET, SUITE 1300, IRVINE, CA, 92614, US

(73) Assignee: INDUSTRIAL TECHNOLOGY RESEARCH INSTITUTE, Hsinchu County (TW)

(21) Appl. No.: 11/558,608

(22) Filed: Nov. 10, 2006

(30) Foreign Application Priority Data
Aug. 21, 2006 (TW) 095130596

(51) Int. Cl. H01S 5/00

(52) U.S. Cl. 372/45.01

(57) ABSTRACT

A light-emitting device includes a substrate, a semiconductor stacked structure positioned on the substrate, a transparent electrode positioned on a first region of the semiconductor stacked structure, and at least one photonic crystal positioned in a second region of the semiconductor stacked structure. Preferably, the first region surrounds the second region, the area of the first region is larger than that of the second region, and the width of the second region is smaller than 40 micrometers. The structure of photonic crystals can be holes, pillars, continuous protrusions or depressions, discontinuous protrusions or depressions or the combination thereof, and the lattice of photonic crystals can be square, hexagonal, rectangular, periodic, multi-periodic, quasi-periodic or non-periodic.

### BACKGROUND OF THE INVENTION

(A) Field of the Invention

The present invention relates to a light-emitting device, and more particularly, to a light-emitting device having photonic crystals and a transparent electrode.

(B) Description of the Related Art

Low output efficiency of light-emitting devices such as light-emitting diode (LED) originates mainly from low light extraction efficiency, which means that the light actually emitted to the exterior of the light-emitting device is only a small portion of the light generated by the light-emitting layer. To solve this low light extraction efficiency problem of the conventional light-emitting device, researchers try to introduce photonic crystals into the light-emitting device to improve the light extraction efficiency.

FIG. 1 shows a conventional light-emitting device 500 disclosed in U.S. Pat. No. 5,955,749. The light-emitting device 500 includes a dielectric structure 512 consisting of an n-type semiconductor 504, a light-emitting layer 506 and a p-type semiconductor 508 and photonic crystals 510 in the dielectric structure 512 have a photonic bandgap. Consequently, a portion of the guided mode in the light-emitting device 500 can be coupled to form a radiation mode, which incorporates a reflective structure between a substrate 502 and the dielectric structure 512 to improve the radiated output light of the light-emitting device 500.

FIG. 2 to FIG. 3(d) show another conventional light-emitting device disclosed in U.S. Pat. No. 6,870,191. According to the technique disclosed in U.S. Pat. No. 6,870,191, an etching process is performed to fabricate a periodic structure 20 on a substrate 10, and an n-type semiconductor 11, a light-emitting layer 12 and a p-type semiconductor 13 are then grown on the periodic structure 20 by an epitaxy process to form a light-emitting device with high external quantum efficiency. In addition, U.S. Pat. No. 6,870,191 also discloses the design of a transparent electrode 34 for the light-emitting device, as shown in FIGS. 3(a)-3(d). The transparent electrode 34 of the conventional light-emitting device entirely covers the surface of the light-emitting device, and the transparent electrode may absorb or attenuate the light emitted from the light-emitting device. To solve this problem, some holes are formed in the transparent electrode such that the light can pass through the transparent electrode via the holes without being absorbed by the transparent electrode, and the light absorbed by the transparent electrode can be reduced. The larger the holes, the less the light absorbed by the transparent electrode, and the utilization efficiency of the light generated in the light-emitting device is improved.

### SUMMARY OF THE INVENTION

One aspect of the present invention provides a light-emitting device, in which the positions, sizes, shapes, and proportions of a transparent electrode and photonic crystals are arranged to diffuse current uniformly via the transparent electrode and to extract light generated in a semiconductor stack structure using the photonic crystals, thereby improving the light extraction efficiency.

The light-emitting device according to this aspect comprises a substrate, a semiconductor stack structure positioned on the substrate, a transparent electrode positioned on a first region of the semiconductor stack structure and at least one photonic crystal positioned in or on a second region of the semiconductor stack structure. The semiconductor stack structure includes an n-type semiconductor layer, a p-type semiconductor layer and a light-emitting layer.

Compared with the prior art, the light-emitting device of the present invention arranges the transparent electrode and the photonic crystals to improve the light extraction efficiency. The transparent electrode of the light-emitting device diffuses the current from the p-type electrode to the p-type semiconductor layer evenly and the photonic crystals extract the light emitted from the light-emitting structure so as to solve the problem of low light extraction efficiency of the conventional light-emitting devices.

### BRIEF DESCRIPTION OF THE DRAWINGS

The objectives and advantages of the present invention will become apparent upon reading the following description and upon reference to the accompanying drawings in which:

FIG. 1 shows a conventional light-emitting device;

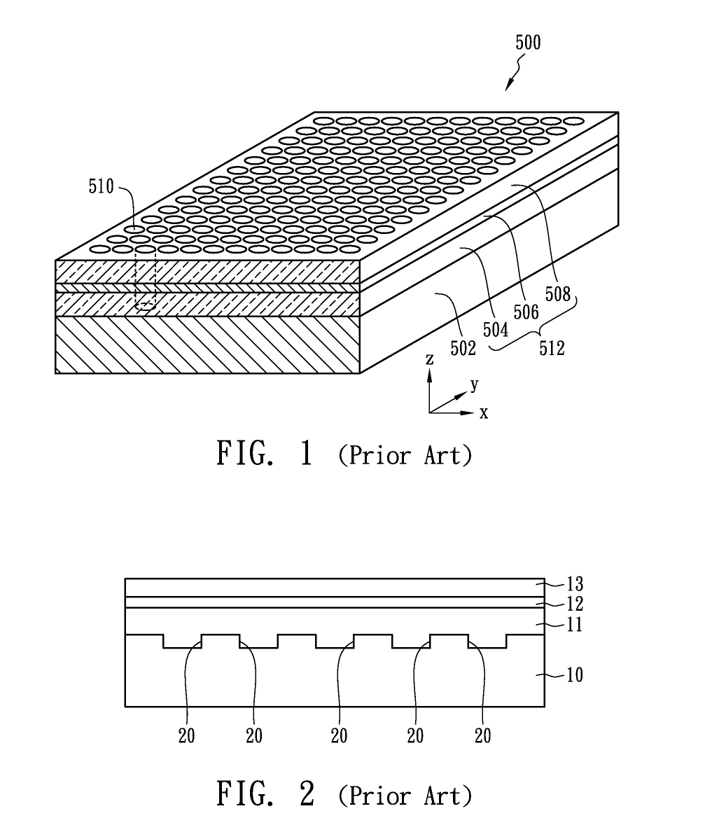

FIGS. 2-3(d) show another conventional light-emitting device;

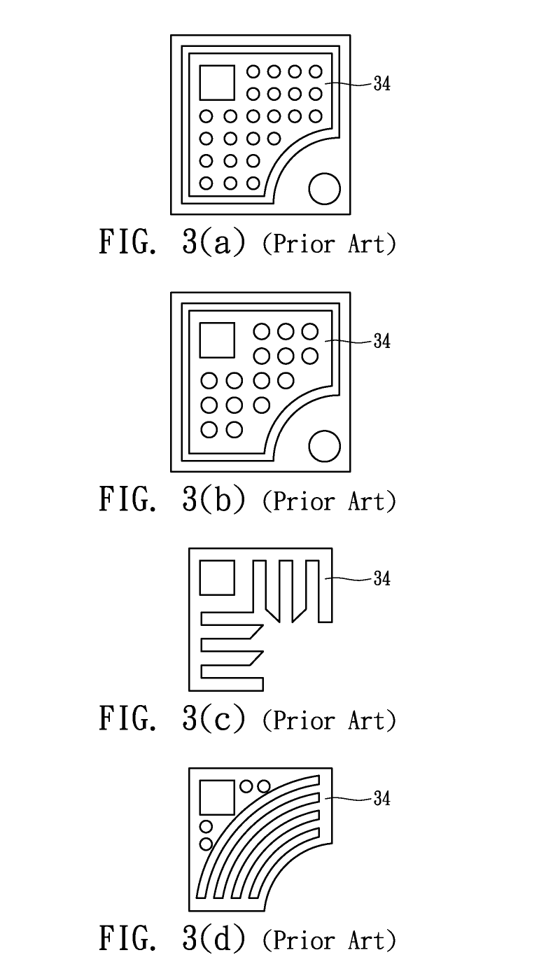

FIG. 4 is a top view of the light-emitting device according to one embodiment of the present invention;

FIG. 5 is a sectional view of the light-emitting device along the cross-section line A-A of FIG. 4 according to one embodiment of the present invention;

FIG. 6 shows the design manner of the transparent electrode according to one embodiment of the present invention;

FIGS. 7-9 show the arrangement of the photonic crystals according to one embodiment of the present invention;

FIGS. 10-12 show the shape of the photonic crystals according to one embodiment of the present invention; and

FIGS. 13-18 show the lattice of the photonic crystals according to one embodiment of the present invention.

### DETAILED DESCRIPTION OF THE INVENTION

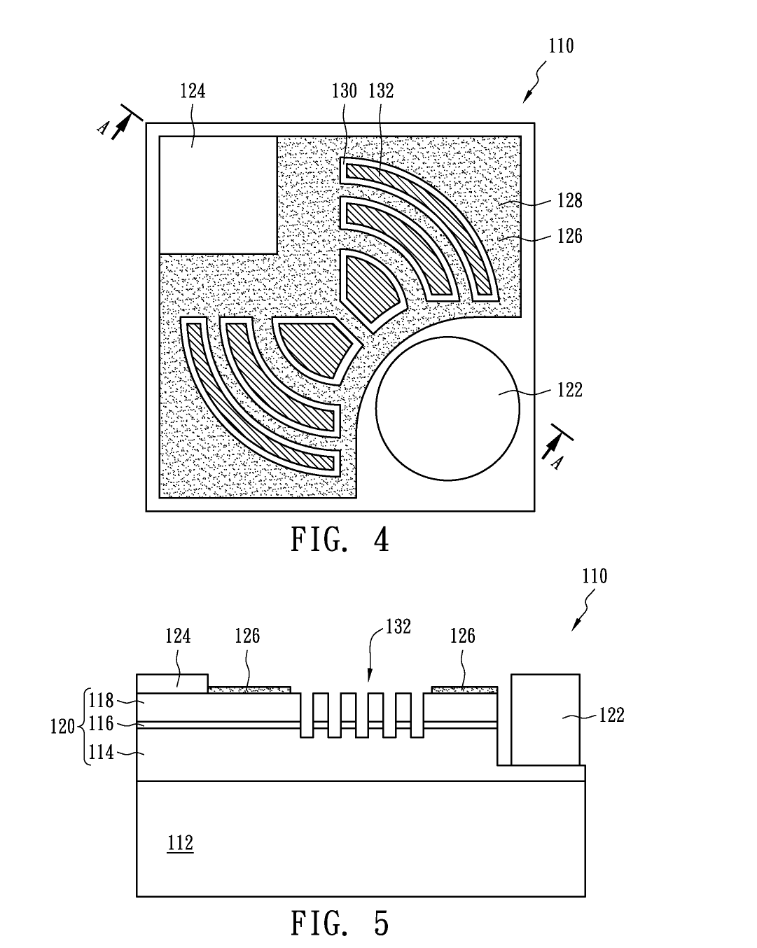

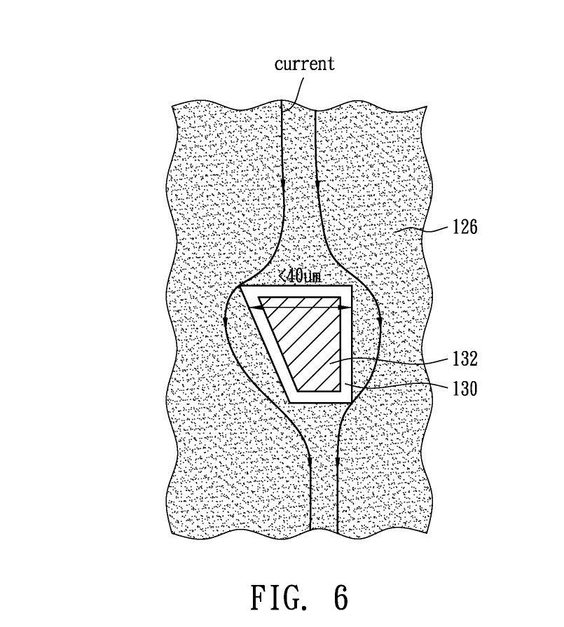

FIGS. 4-6 show the light-emitting device 110 according to one embodiment of the present invention. The light-emitting device 110 includes a substrate 112, a semiconductor stack structure 120 positioned on the substrate 112, a transparent electrode 126 positioned on a first region 128 of the semiconductor stack structure 120, a plurality of photonic crystals 132 positioned in or on a second region 130 of the semiconductor stack structure 120. The substrate 112 can be made of one material selected from the group consisting of aluminum oxide (sapphire), silicon carbide (SiC), silicon (Si), gallium arsenide (GaAs) and aluminum nitride (AIN).

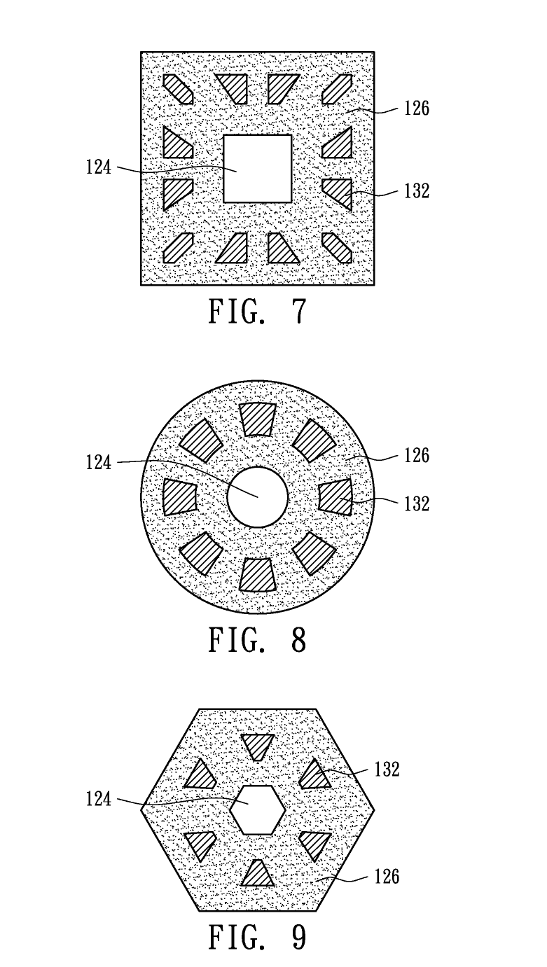

The semiconductor stack structure 120 includes an n-type semiconductor layer 114, a p-type semiconductor layer 118 and a light-emitting layer 116 positioned between the n-type semiconductor layer 114 and the p-type semiconductor layer 118. The light-emitting device 110 further includes an n-type electrode 122 positioned on the n-type semiconductor layer 114 and a p-type electrode 124 positioned on the p-type semiconductor layer 118. Preferably, the first region 128 surrounds the second region 130, and the area of the first region 128 is larger than the total area of the second regions 130. The width of the second region 130 is smaller than 40 μm, so as to prevent the uneven diffusion of current due to the overlarge gap of the transparent electrode 126, as shown in FIG. 6.

The embodiment of the present invention can be a light-emitting diode (LED), and the material of the substrate is sapphire. An epitaxy structure consisting of an n-type gallium nitride layer (n-GaN), an active light-emitting layer, and a p-type gallium nitride layer (p-GaN) is disposed on the substrate, in which the distance between the n-GaN and the substrate is smaller than the distance between the p-GaN to the substrate, and the active light-emitting layer is position between the n-GaN and the p-GaN. A dielectric layer made of material such as silicon oxide (SiOx) or silicon nitride (SiNx) can be fabricated on the p-GaN by chemical vapor deposition process. A photoresist is then coated on the dielectric layer, and the pattern of the photonic crystals is fabricated in the photoresist by interference lithography, electron beam lithography or photolithography. Subsequently, the pattern of the photonic crystals is transferred from the photoresist to the dielectric layer by an etching process, and nickel metal is evaporated by E-gun to serve as a mask for the subsequent pattern transfer.

Finally, the Ni-metal mask is etched to fabricate the pattern of the photonic crystals in the epitaxial material. When fabricating the pattern of the photonic crystal in the photoresist, the region of the transparent electrode can be reserved by photolithography, and the photonic crystal is not fabricated in this reserved region. Therefore, after the photonic crystal is fabricated, the transparent electrode can be fabricated in the reserved region through metal evaporation and rapid thermal annealing. In particular, the active light-emitting layer can emit light after current is injected into respective electrodes on the p-GaN and the n-GaN, and the photonic crystals in the epitaxial material can convert the guided mode in a part of the epitaxy layer to the radiation mode as the light emitted from the active light-emitting layer, thereby improving the external light extraction efficiency. After actual measurement, the transparent electrode of the present invention diffuses the current evenly, and the light intensity measured right above the light-emitting device is increased by at least 10%.

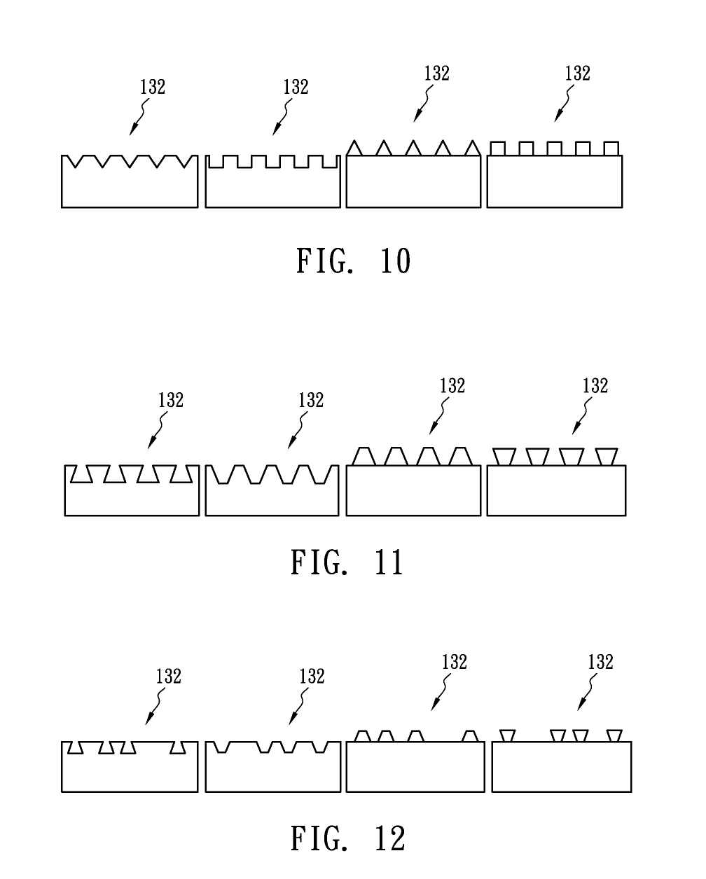

FIGS. 7-9 show the arrangement of the photonic crystals 132 and the transparent electrode 126 according to one embodiment of the present invention. In order to enable the sum of the output light quantity obtained by the current injected into the transparent electrode 126 and the output light quantity obtained by the converting of the guided mode to the radiation mode by the photonic crystals 132 to improve the light extraction efficiency of the light-emitting device 110, the positions, sizes, and shapes of the transparent electrode 126 (i.e., the first region 128) and the photonic crystals 132 (i.e., the second region 130) can be designed in accordance with the position and current distribution of the transparent electrode 126, such that the current can flow smoothly, the photonic crystals 132 have maximum output light quantity, and the LED has the lowest electrical impedance. As shown in FIGS. 7-9, the photonic crystals 132 (i.e., the second region 130) are surrounded by the transparent electrode 126 (i.e., the first region 128), and the area ratio of the second region 130 to the first region 128 is less than 0.5. In other words, the second region 130 occupied by the photonic crystals 132 is entirely surrounded by the transparent electrode 126, and the area ratio of the photonic crystals 132 to the transparent electrode 126 is less than 0.5 and not equal to 0.

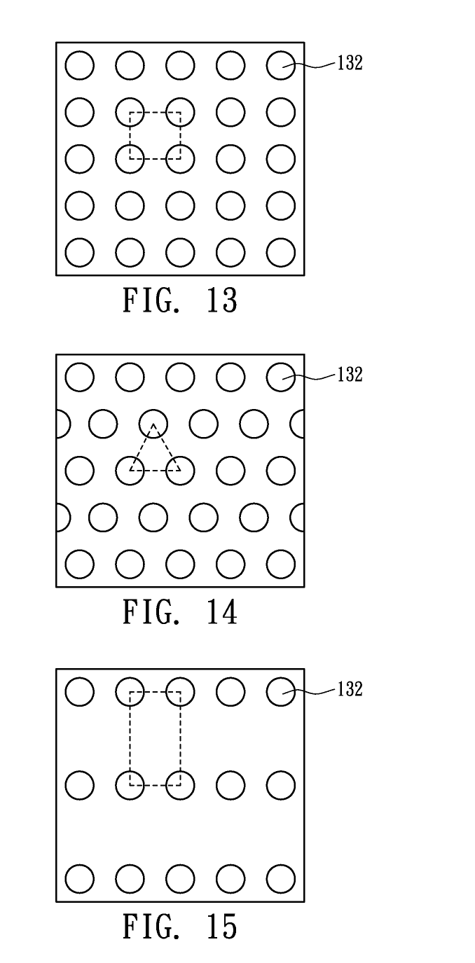

FIGS. 10-12 show the shape of the photonic crystals 132 according to one embodiment of the present invention. The shape of the photonic crystals 132 can be holes, pillars, continuous protrusions or depressions, discontinuous protrusions or depressions or the combination thereof. The holes can be circular, elliptic, conic, n-sided (polygonal)or tapered, where n is a positive integer larger than or equal to 3. The pillars can be circular, elliptic, conic, m-sided (polygonal) or tapered, where m is a positive integer larger than or equal to 3.

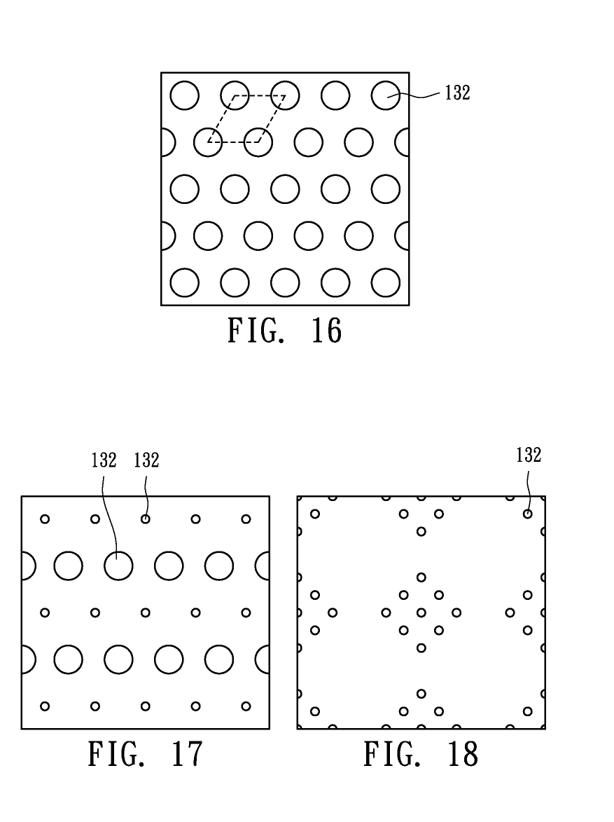

FIGS. 13-18 show the lattice of the photonic crystals 132, which can be square, hexagonal, rectangular, periodic, multi-periodic, quasi-periodic or non-periodic.

Though U.S. Pat. No. 5,955,749 has disclosed a dielectric structure having photonic crystals, the dielectric structure does not include a transparent electrode. The light-emitting device 110 of the present invention arranges the transparent electrode 126 and the photonic crystals 132 in a mixture manner, so as to improve the light extraction efficiency of the light-emitting device 110. Moreover, U.S. Pat. No. 6,870,191 mainly focuses on the design of the transparent electrode 34 to reduce the area covered by the transparent electrode 34 so as to decrease the light absorbed by the transparent electrode 34. In addition to adopting the design of the transparent electrode 126, the present invention also uses the photonic crystals 132 positioned on the second region 130 without the transparent electrode 126, thereby improving the light extraction efficiency of the light-emitting device 110. In brief, the light-emitting device 110 of the present invention uses the transparent electrode 126 to diffuse the current from the p-type electrode 124 to the p-type semiconductor layer 118 evenly, and uses the photonic crystals 132 to extract the light emitted from the light-emitting structure 120, so as to solve the problem of low light extraction efficiency of the conventional light-emitting devices.

The above-described embodiments of the present invention are intended to be illustrative only. Numerous alternative embodiments may be devised by those skilled in the art without departing from the scope of the following claims.

What is claimed is:

1. A light-emitting device, comprising:
a substrate;
a stacked structure including an n-type semiconductor layer, an active light-emitting layer and a p-type semiconductor layer formed on one side of the substrate;
a photonic crystal formed in a partial region of the stacked structure; and
a transparent electrode formed on a partial surface of the stacked structure, wherein no photonic crystal exists in the transparent electrode.

2. The light-emitting device as claimed in claim 1, wherein the substrate comprises at least one material selected from the group consisting of aluminum oxide, silicon carbide, silicon, gallium arsenide and aluminum nitride.

3. The light-emitting device as claimed in claim 1, wherein the shape of the photonic crystal is holes, pillars, continuous protrusions or depressions, discontinuous protrusions or depressions or the combination thereof.

4. The light-emitting device as claimed in claim 1, wherein the lattice of the photonic crystal is square, hexagonal, rectangular, periodic, multi-periodic, quasi-periodic or non-periodic.

5. The light-emitting device as claimed in claim 1, wherein the region occupied by the photonic crystal is surrounded by the transparent electrode, and the area ratio of the region occupied by the photonic crystal to the region occupied by the transparent electrode is less than 0.5 and not equal to 0.

6. The light-emitting device as claimed in claim 3, wherein the holes are circular, elliptic, conic, n-sided or tapered.

7. The light-emitting device as claimed in claim 6, wherein n is a positive integer larger than or equal to 3.

8. The light-emitting device as claimed in claim 3, wherein the pillars are circular, elliptic, conic, m-sided or tapered.

9. The light-emitting device as claimed in claim 8, wherein m is a positive integer larger than or equal to 3.

10. A light-emitting device, comprising:
a substrate;
a light-emitting structure positioned on the substrate;
a transparent electrode positioned on a first region of the light-emitting structure; and
at least one photonic crystal positioned in a second region of the light-emitting structure.

11. The light-emitting device as claimed in claim 10, wherein the area of the first region is larger than the area of the second region.

12. The light-emitting device as claimed in claim 10, wherein the first region surrounds the second region.

13. The light-emitting device as claimed in claim 10, wherein the width of the second region is smaller than 40 micrometers.

14. The light-emitting device as claimed in claim 10, wherein the light-emitting structure includes an n-type semiconductor layer, an active light-emitting layer and a p-type semiconductor layer.

15. The light-emitting device as claimed in claim 10, wherein the substrate comprises at least one material selected from the group consisting of aluminum oxide, silicon carbide, silicon, gallium arsenide and aluminum nitride.

16. The light-emitting device as claimed in claim 10, wherein the shape of the photonic crystal is holes, pillars, continuous protrusions or depressions, discontinuous protrusions or depressions or the combination thereof.

17. The light-emitting device as claimed in claim 10, wherein the lattice of the photonic crystal is square, hexagonal, rectangular, periodic, multi-periodic, quasi-periodic or non-periodic.

18. The light-emitting device as claimed in claim 16, wherein the holes are circular, elliptic, conic, n-sided or tapered.

19. The light-emitting device as claimed in claim 18, wherein n is a positive integer larger than or equal to 3.

20. The light-emitting device as claimed in claim 16, wherein the pillars are circular, elliptic, conic, m-sided or tapered.

21. The light-emitting device as claimed in claim 20, wherein m is a positive integer larger than or equal to 3.
